(19) United States
(12) Patent Application Publication
(10) Pub. No.: US 2019/0011831 A1
(43) Pub. Date: Jan. 10, 2019

(54) Method for Manufacturing Display Substrate

(71) Applicant: BOE TECHNOLOGY GROUP CO., LTD., Beijing (CN)

(72) Inventors: Wei LI, Beijing (CN); Zhen SONG, Beijing (CN); Dini XIE, Beijing (CN)

(21) Appl. No.: 15/744,966

(22) PCT Filed: Jul. 7, 2017
(86) PCT No.: PCT/CN2017/092195

§ 371 Date: Jan. 15, 2018

(30) Foreign Application Priority Data
Nov. 16, 2016 (CN) 201611030764.0

(51) Int. Cl. G03F 7/00; H01L 27/32; H01L 51/56; B41J 2/01

(52) U.S. Cl. CPC G03F 7/0002; H01L 27/32; B82Y 40/00; B41J 2/01; H01L 51/56

(57) ABSTRACT

The present disclosure provides a method for manufacturing a display substrate, relating to the field of manufacturing technology for display substrate, and can address at least in part a problem of insufficient flatness of a planarization layer, complex manufacturing process and high cost of a prior art display substrate. The method for manufacturing a display substrate according to the present disclosure includes: forming a curable material layer on a base, the base having a first structure; performing imprinting on the curable material layer using a nano-imprinting mold, so that the curable material layer is planarized, and at the same time a through hole connected to the first structure is formed in the curable material layer; curing the curable material layer to form a planarization layer; and forming a second structure connected to the first structure via the through hole.

### CROSS-REFERENCE TO RELATED APPLICATIONS

The present application claims the priority of Chinese Patent Application No. 201611030764.0, filed on Nov. 16, 2016, the contents of which are incorporated herein in their entirety by reference.

### TECHNICAL FIELD

The present disclosure relates to the field of manufacturing technology for display substrate, and in particular relates to a method for manufacturing a display substrate.

### BACKGROUND

An inkjet printing process is frequently employed for manufacturing a display device such as an organic light emitting diode (OLED) due to advantages such as low cost, simple process, high precision and the like. However, as shown in FIG. 1, in an OLED array substrate of the prior art, various display structures, such as gate lines, data lines, thin-film transistors (TFT) and the like provided on a base 09, are placed at different positions and have different heights (thicknesses), which may result in steps and may influence a subsequent inkjet printing process.

In the prior art, a method for eliminating steps includes: covering these display structures with a planarization layer 01; and forming a through hole 011 in the planarization layer 01 by a lithography process, wherein the through hole 011 is for connecting components (such as an anode of an OLED (not shown)) formed on the planarization layer 01 with components (such as a drain 02 of a TFT) covered by the planarization layer 01. However, as shown in FIG. 1, the planarization layer 01 manufactured by the existing method does not have sufficient capability of eliminating steps, its upper surface still having ups and downs, and the flatness thereof cannot satisfy requirements of an inkjet printing process. Meanwhile, the through hole 011 in the planarization layer 01 needs to be formed by a separate lithography process, which requires the use of a mask plate, making the process complex and the cost high.

### SUMMARY

The present disclosure provides a method for manufacturing a display substrate.

According to an aspect of the present disclosure, a method for manufacturing a display substrate includes:

forming a curable material layer on a base, the base having a first structure;

performing imprinting on the curable material layer using a nano-imprinting mold, so that the curable material layer is planarized, and at the same time a through hole connected to the first structure is formed in the curable material layer;

curing the curable material layer to form a planarization layer; and

forming a second structure connected to the first structure via the through hole.

According to an embodiment of the present disclosure, the first structure may include a thin film transistor (TFT).

According to an embodiment of the present disclosure, the display substrate may be an organic light emitting diode (OLED) array substrate; and the second structure may include one of an anode and a cathode of the OLED, and the one of the anode and the cathode is connected to a drain of the TFT via the through hole.

According to an embodiment of the present disclosure, the method may further include, after the forming the second structure, forming a light emitting layer of the OLED by an inkjet printing process.

According to an embodiment of the present disclosure, the curable material layer may include one of a light-curable material and a heat-curable material.

According to an embodiment of the present disclosure, the curable material layer may contain fluorine and/or silicon.

According to an embodiment of the present disclosure, the fluorine and silicon in the curable material layer may have a total mass percentage in a range from 20% to 40%.

According to an embodiment of the present disclosure, the curable material layer may include an inorganic silicon and organic hybrid light-curable material.

According to an embodiment of the present disclosure, the curing the curable material layer may include: curing the curable material layer in a state where the nano-imprinting mold is kept being pressed onto the curable material layer.

According to an embodiment of the present disclosure, the curable material layer may have a thickness in a range from 2 microns to 2.5 microns.

### BRIEF DESCRIPTION OF THE DRAWINGS

FIG. 1 is a schematic diagram of a structure after forming a planarization layer in a method for manufacturing an OLED array substrate according to the prior art;

FIG. 2 is a schematic diagram of a structure after forming a curable material layer in a method for manufacturing a display substrate according to an embodiment of the present disclosure;

FIG. 3 is a schematic diagram of a nano-imprinting process in a method for manufacturing a display substrate according to an embodiment of the present disclosure;

FIG. 4 is another schematic diagram of a nano-imprinting process in a method for manufacturing a display substrate according to an embodiment of the present disclosure;

FIG. 5 is a schematic diagram of an ultraviolet (UV) light-curing process in a method for manufacturing a display substrate according to an embodiment of the present disclosure; and

FIG. 6 is a schematic diagram of a structure after forming a planarization layer in a method for manufacturing a display substrate according to an embodiment of the present disclosure.

### DETAILED DESCRIPTION

To make one of ordinary skill in the art better understand the technical solutions according to the present disclosure, the present disclosure will be further described in detail below with reference to the accompanying drawings and embodiments.

A method for manufacturing a display substrate according to an embodiment of the present disclosure includes: forming a curable material layer on a base, the base having a first structure; performing imprinting on the curable material layer using a nano-imprinting mold, so that the curable material layer is planarized, and at the same time a through hole connected to the first structure is formed in the curable material layer; curing the curable material layer to form a planarization layer; and forming a second structure connected to the first structure via the through hole.

The method for manufacturing a display substrate according to the embodiment includes a step of flattening the curable material layer using the nano-imprinting mold while (at the same time) forming a through hole therein, therefore, on one hand it is ensured that the planarization layer has a very good flatness, and on the other hand it is not necessary to form the through hole separately by, for example, a lithography process, thereby simplifying the process and reducing the cost.

A method for manufacturing a display substrate according to another embodiment of the present disclosure includes steps S201 to S207 described in detail in the following.

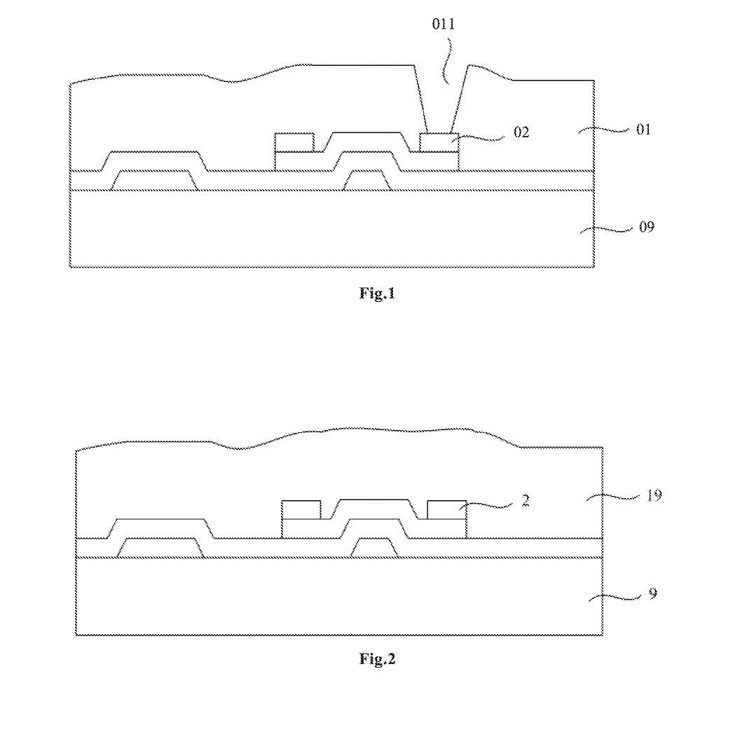

At step S201, a curable material layer 19 is formed on a base 9 having a first structure. That is, as shown in FIG. 2, the first structure is formed on the base 9 at first, and then a curable material is coated on the base 9, or the base 9 is covered with the curable material, to form the curable material layer 19.

The first structure may include a thin film transistor (TFT). In this case, a drain 2 of the TFT needs to be connected to another component (such as an anode or cathode of an organic light emitting diode (OLED)) via a through hole 11 (referring to FIG. 6) which will be formed in a planarization layer 1, to obtain a driving current. However, the first structure is not limited to a TFT, and may include any structure(s) required to be connected to another structure on the planarization layer 1 via the through hole 11. In addition to the first structure, other structures such as gate lines, data lines or the like may be formed on the base 9.

The curable material layer 19 may include a light-curable material or a heat-curable material. A curable material is in a liquid state with certain fluidity under a normal condition, and can be cured under a certain condition. In order for simplicity of process, the curable material layer 19 may be cured by employing a light-curing process or a heat-curing process.

The curable material layer 19 may include a curable resin. The curable material layer 19 may contain fluorine and/or silicon, and fluorine and silicon in the curable material layer 19 may have a total mass percentage in a range from 20% to 40%.

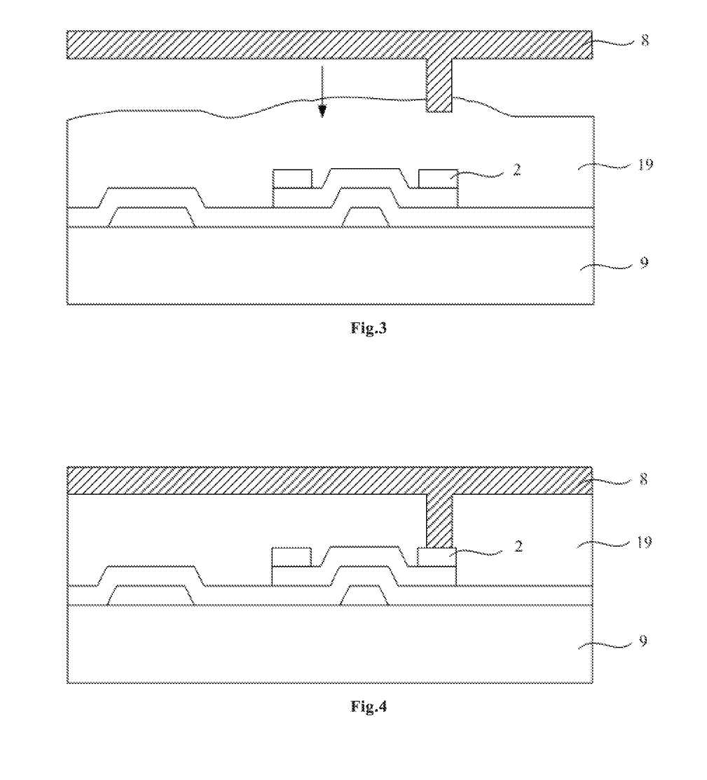

The method for manufacturing a display substrate according to an embodiment of the present disclosure may further include a step of planarizing the curable material layer 19 by a nano-imprinting process. During the nano-imprinting process, in order to enable the curable material layer 19 to be well separated from a nano-imprinting mold 8 (referring to FIG. 3) without adhering thereto, the curable material layer 19 is required to have a relatively low surface energy. Studies show that when the curable material layer 19 contains fluorine and/or silicon, the surface energy thereof can be lowered.

The curable material layer 19 may include an inorganic silicon and organic hybrid light-curable material, for example, a nano-silica/organosilicon hybrid material, vinyl group polysilsesquioxane, benzene trapezoid polysilsesquioxane, organosilicon vinyl ether, epoxy group polyorgano siloxane, or the like.

The curable material layer 19 may have a thickness in a range from 2 microns to 2.5 microns. The curable material layer 19 (or the planarization layer 1) may need a sufficient thickness to ensure flatness, but if the curable material layer 19 is too thick, then it may influence electric connections or the like. It is discovered by study that a thickness range from 2 microns to 2.5 microns is suitable for ensuring flatness while protecting electric connections.

At step S202, prebaking may be performed on the curable material layer 19. That is, the curable material layer 19 may be preheated to improve its degree of cure to a certain extent, keeping the shape of the curable material layer 19 stable. This prebaking step may include heating for 2-3 minutes at a temperature of 180□.

At step S203, as shown in FIGS. 3 and 4, imprinting may be performed on the curable material layer 19 using the nano-imprinting mold 8, to planarize the curable material layer 19, while, at the same time, form the through hole 11 connected to the first structure in the curable material layer 19.

A nano-imprinting process refers to a process in which a mold having a nano-pattern is pressed onto a material layer, thereby forming an imprinted nano-pattern in the material layer. As shown in FIGS. 3 and 4, the nano-imprinting mold 8 may be pressed onto the curable material layer 19. The nano-imprinting mold 8 may be formed of a material such as quartz or the like. The nano-imprinting mold 8 may have a protrusion, which is located at a position corresponding to the through hole 11 to be formed in the curable material layer 19. The protrusion may have a shape including a shape of a column or the like. The nano-imprinting mold 8 may include a planar portion, which corresponds to positions of the curable material layer 19 where no through hole 11 is to be formed. Thus, by the nano-imprinting process, it is possible on one hand to “press and flatten” most of an upper surface of the curable material layer 19, to improve the flatness thereof, and it is possible on the other hand to form the through hole 11 at a desired position at the same time.

At step S204, the curable material layer 19 is cured to form the planarization layer 1. That is, a curing condition for the curable material layer 19 is triggered so that the curable material layer 19 is cured to have a fixed form, to form the planarization layer 1.

Due to the above-described nano-imprinting process, the planarization layer 1 formed in the present embodiment has a high surface flatness, which can satisfy requirements of a subsequent process such as inkjet printing; and the planarization layer 1 already has the through hole 11 formed therein, so there is no need to form the through hole 11 separately as in the prior art (for example, by a lithography process), thereby simplifying the manufacturing process and reducing the cost.

The step S204 may include: curing the curable material layer 19 in a state where the nano-imprinting mold 8 is kept being pressed onto the curable material layer 19. That is, after completing the nano-imprinting process, the nano-imprinting mold 8 may not be removed (that is, mold unloading may not be performed), and the curable material layer 19 may be cured while having the nano-imprinting mold 8 thereon, to prevent the curable material layer 19 from deforming due to separation from the nano-imprinting mold 8 before being completely cured.

The method for curing may be dependent on the type of the curable material layer 19. If the curable material layer 19 includes a light-curable material, then the step S204 may include irradiating the curable material layer 19 with ultraviolet (UV) light; if the curable material layer 19 includes a heat-curable material, then the step S204 may include heating the curable material layer 19.

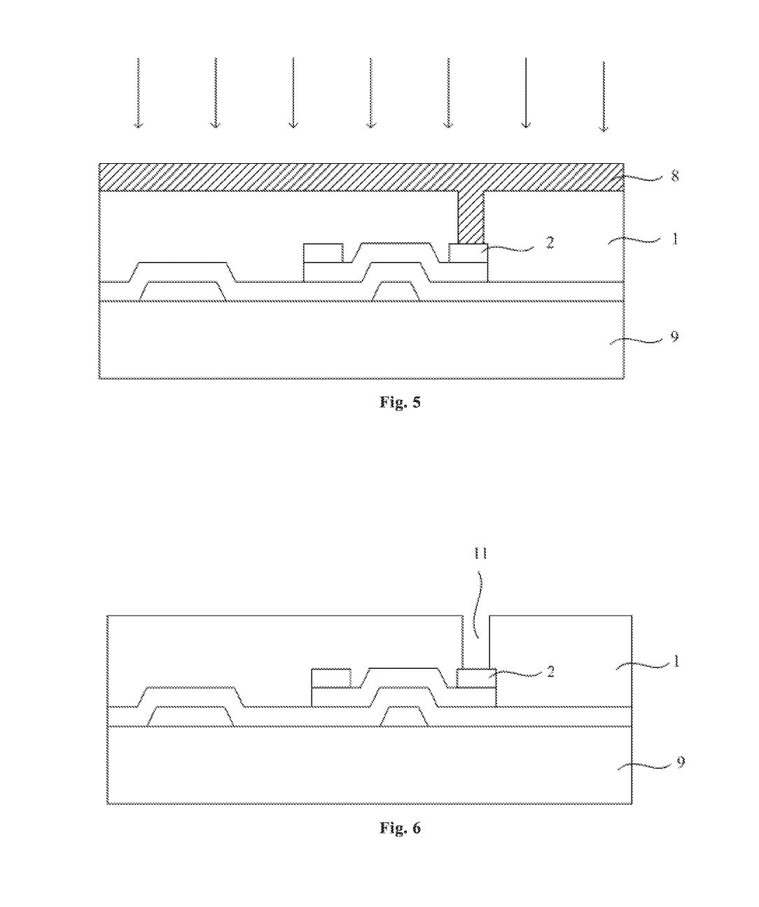

Specifically, as shown in FIG. 5, if the curable material layer 19 includes a light-curable material, and the nano-imprinting mold 8 is formed of quartz, then the curing step may include: irradiating the curable material layer 19 with UV light from a side of the nano-imprinting mold 8 distal to the base 9. This is possible because the nano-imprinting mold 8 formed of quartz is transparent.

At step S205, the nano-imprinting mold 8 may be removed, and postbaking may be performed. That is, the nano-imprinting mold 8 may be unloaded, and postbaking may be performed thereafter, to further fix the shape of the planarization layer 1, resulting in a structure as shown in FIG. 6. Specifically, the postbaking may include heating for 60 minutes at a temperature of 250□.

At step S206, a second structure may be formed, and the second structure may be connected to the first structure via the through hole 11. That is, after forming the planarization layer 1, other structure(s) may be formed thereon, such as the second structure, and the other structure(s) may be connected to the first structure via the through hole 11 in the planarization layer 1.

A display substrate, manufactured by the method for manufacturing a display substrate according to an embodiment of the present disclosure, may be an OLED array substrate. In this case, the OLED may be provided on the planarization layer 1, and the second structure may include an anode of the OLED. The anode may be connected to the first structure (such as the drain 2 of the TFT) via the through hole 11. The second structure may also include a cathode of the OLED, and the cathode may be connected to the first structure (such as the drain 2 of the TFT) via the through hole 11.

It is to be understood that the second structure is not limited to the anode or the cathode of the OLED, and may also include a pixel electrode of a liquid crystal display array substrate or the like, which may also be connected to the first structure via the through hole 11.

At step S207, inkjet printing may be performed on the planarization layer 1. For example, in a case where the display substrate is an OLED array substrate, a light emitting layer of the OLED may be formed by the inkjet printing process. The method according to an embodiment of the present disclosure can ensure that the planarization layer 1 has a relatively high flatness, satisfying the requirements of the inkjet printing. Thus, the light emitting layer and the like may be formed on the planarization layer 1 by the inkjet printing process, thereby simplifying the process and reducing the cost.

The OLED array substrate may have various types such as a top-reflection type, a bottom-reflection type or the like.

It can be understood that the foregoing implementations are merely exemplary implementations used for describing the principle of the present disclosure, but the present disclosure is not limited thereto. Those of ordinary skill in the art may make various variations and modifications without departing from the spirit and essence of the present disclosure, and these variations and modifications shall fall into the protection scope of the present disclosure.

What is claimed is:

1. A method for manufacturing a display substrate, comprising:
forming a curable material layer on a base, the base having a first structure;
performing imprinting on the curable material layer using a nano-imprinting mold, so that the curable material layer is planarized, and at the same time a through hole connected to the first structure is formed in the curable material layer;
curing the curable material layer to form a planarization layer; and
forming a second structure connected to the first structure via the through hole.

2. The method for manufacturing a display substrate according to claim 1, wherein the first structure comprises a thin film transistor (TFT).

3. The method for manufacturing a display substrate according to claim 2, wherein
the display substrate is an organic light emitting diode (OLED) array substrate; and
the second structure comprises one of an anode and a cathode of the OLED, and the one of the anode and the cathode is connected to a drain of the TFT via the through hole.

4. The method for manufacturing a display substrate according to claim 3, further comprising, after the forming the second structure,
forming a light emitting layer of the OLED by an inkjet printing process.

5. The method for manufacturing a display substrate according to claim 1, wherein the curable material layer comprises one of a light-curable material and a heat-curable material.

6. The method for manufacturing a display substrate according to claim 1, wherein the curable material layer contains fluorine and/or silicon.

7. The method for manufacturing a display substrate according to claim 6, wherein the fluorine and silicon in the curable material layer have a total mass percentage in a range from 20% to 40%.

8. The method for manufacturing a display substrate according to claim 1, wherein the curable material layer comprises an inorganic silicon and organic hybrid light-curable material.

9. The method for manufacturing a display substrate according to claim 1, wherein the curing the curable material layer comprises:
curing the curable material layer in a state where the nano-imprinting mold is kept being pressed onto the curable material layer.

10. The method for manufacturing a display substrate according to claim 1, wherein the curable material layer has a thickness in a range from 2 microns to 2.5 microns.
